(19) United States
(12) Patent Application Publication
(10) Pub. No.: US 2026/0266895 A1
(43) Pub. Date: Sep. 10, 2026

(54) AUDIO BUS LINE FAULT PROTECTION CIRCUITRY

(71) Applicant: Analog Devices International Unlimited Company, Limerick (IE)

(72) Inventors: Prashant Tripathi, Jaipur (IN); Ravikumar BHAMIDIPATI, Bengaluru (IN); Stuart PATTERSON, East Walpole, MA (US)

(21) Appl. No.: 19/070,177

(22) Filed: Mar. 4, 2025

(51) Int. Cl. G01R 31/28; H02H 9/04; H04R 3/00

(52) U.S. Cl. CPC G01R 31/2839; G01R 31/2889; H02H 9/046; H04R 3/007

(57) ABSTRACT

In an aspect, an integrated circuit (IC) is provided. The IC includes pins. The IC further includes line fault diagnostic circuitry, connected to the pins. The line fault diagnostic circuitry includes a first set of active elements and passive elements, configured to provide a line fault diagnostic functionality of the IC by detecting and classifying line faults on the pins. The IC also includes over-voltage protection circuitry, connected to the pins and the line fault diagnostic circuitry. The over-voltage protection circuitry includes a second set of active elements and passive elements, configured to preserve a normal functionality of the IC including the line fault diagnostic functionality of the IC by applying over-voltage compensation techniques including voltage reduction and voltage avoidance to the pins and the line fault diagnostic circuitry during an over-voltage line fault that exceeds a maximum voltage threshold of at least the pins.

### FIELD OF THE DISCLOSURE

This disclosure relates to apparatus and methods for network communications, and, in particular, to audio bus line fault protection circuitry.

### BACKGROUND

In traditional passenger electric vehicle (EV) architecture, the maximum battery voltage can be 18V. Recently, there has been interest in 48V EV architectures. While communication technologies such as, but not limited to, Automotive Audio Bus (A2B) digital audio bus technology, an audio distribution protocol developed by Analog Devices®, may be used in the same wiring harness as a 48V battery power supply, protections from critical line faults like shorts to battery voltage are needed. Current A2B chips support an AMVR (Absolute Max Voltage Rating) of 30V.

Accordingly, there is a need to provide an integrated circuit (IC)-based communication bus that uses an existing protocol (e.g., A2B) to avoid having to redesign the IC to use with a new protocol.

### SUMMARY OF THE DISCLOSURE

The present disclosure provides apparatus and methods relating to audio bus protection circuitry, and, in particular, to Automotive Audio Bus (A2B) protection circuitry for a 48V architecture.

In an aspect, an integrated circuit (IC) is provided. The IC includes a plurality of pins. The IC further includes line fault diagnostic circuitry, connected to the plurality of pins. The line fault diagnostic circuitry includes a first set of active elements and passive elements. The line fault diagnostic circuitry is configured to provide a line fault diagnostic functionality of the IC by detecting and classifying line faults on the plurality of pins. The IC also includes over-voltage protection circuitry, connected to the plurality of pins and the line fault diagnostic circuitry. The over-voltage protection circuitry includes a second set of active elements and passive elements. The over-voltage protection circuitry is configured to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

In another aspect, a method for protecting an integrated circuit (IC) is provided. The method includes configuring a line fault diagnostic circuitry, connected to a plurality of pins of the IC. The line fault diagnostic circuitry includes a first set active elements and passive elements. The method configures the line fault diagnostic circuitry to provide a line fault diagnostic functionality of the IC by detecting and classifying line faults on the plurality of pins. The method further includes configuring an over-voltage protection circuitry. The over-voltage protection circuitry is connected to the plurality of pins and the line fault diagnostic circuitry. The over-voltage protection circuitry includes a second set of active elements and passive elements. The method configures the over-voltage protection circuitry to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

### BRIEF DESCRIPTION OF THE DRAWINGS

The present invention will now be described in more detail with reference to the accompanying drawings, which are not intended to be limiting:

FIG. 1 is a block diagram of an illustrative two-wire communication system, in accordance with various aspects;

FIG. 2 is a block diagram of a node transceiver that may be included in a node of the system of FIG. 1, in accordance with various aspects;

FIG. 3 is a circuit diagram of conventional bus bias circuitry for an A2B main node;

FIG. 4 is circuit diagram of example bus bias circuitry corresponding to a first solution, in accordance with an exemplary aspect;

FIG. 5 is a circuit diagram of example bus bias circuitry corresponding to the first solution, in accordance with an exemplary aspect;

FIG. 6 is a circuit diagram of example bus bias circuitry corresponding to a second solution, in accordance with an exemplary aspect;

FIG. 7 is a circuit diagram of example bus bias circuitry corresponding to a third solution, in accordance with an exemplary aspect;

FIG. 8 is a circuit diagram of example bus bias circuitry corresponding to a fourth solution, in accordance with an exemplary aspect;

FIG. 9 is a circuit diagram of conventional A2B bus circuitry in a bus powered sub (BPS) node;

FIG. 10 is a circuit diagram of example A2B bus circuitry in a bus powered sub (BPS) node, in accordance with an exemplary aspect;

FIG. 11 is a flow diagram of an example method for protecting an integrated circuit from an over-voltage fault, in accordance with an exemplary aspect; and

FIG. 12 is a flow diagram of further blocks of the method of FIG. 11, in accordance with an exemplary aspect.

### DETAILED DESCRIPTION

The present disclosure provides apparatus and methods relating to audio bus protection circuitry, and, in particular, to Automotive Audio Bus (A2B) protection circuitry for a 48V architecture. In an aspect, the 48V architecture corresponds to a battery for powering an electronic control unit (ECU) of an electric vehicle (EV). While aspects of the present disclosure are primary described with respect to A2B protection circuitry for a 48V architecture, aspects of the present disclosure can be readily applied to any voltage architecture by simply changing values of active and/or passive elements of the various protection circuitries described herein.

In traditional passenger vehicle architecture, the maximum battery voltage can be 18V, which is not harmful for integrated circuit (IC) pins of a transceiver because the short to battery fault does not expose the pins above their Absolute Max Voltage Rating (AMVR) which is 30V. The use of a 48V battery to power ECUs in future EVs is creating interest. A2B products provide comprehensive line fault diagnostics information by sensing the communication line for various line faults. Some of the IC pins which are used for sensing the line voltage are directly exposed to the battery voltage during short to battery faults. However, short to battery faults will now expose the A2B IC pins to 48V or higher voltages, which is higher than the absolute maximum rating of the IC pins.

The present solution safeguards IC pins from high-voltage battery shorts, e.g., exposure of an IC pin to a voltage greater than an absolute maximum voltage rating, while maintaining the detailed line fault diagnostic capabilities of the A2B transceiver.

In an aspect, an IC includes line fault diagnostic circuitry, connected to a plurality of pins, configured to provide a line fault diagnostic functionality of the IC by detecting and classifying line faults on the plurality of pins; and

In an aspect, the IC further includes over-voltage protection circuitry, connected to the plurality of pins and the line fault diagnostic circuitry, configured to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault. In an aspect, the over-voltage line faults exceeds a maximum voltage threshold of at least the plurality of pins.

In an aspect, the over-voltage protection circuitry is configured to preserve the normal functionality of the IC from the over-voltage line fault by reducing an amount of voltage the plurality of pins are exposed to during the over-voltage line fault to be less than the maximum voltage threshold of at least the plurality of pins.

In an aspect, the over-voltage protection circuitry is configured to preserve the normal functionality of the IC from the over-voltage line fault by turning off, during the over-voltage line fault, any of the active elements of the line fault diagnostic circuitry that are susceptible to over-voltage damage.

In an aspect, the over-voltage protection circuitry is configured to preserve a normal functionality of the IC from the over-voltage line fault by controlling at least one of the active elements of the over-voltage protection circuitry to alter a current path in the IC used by at least one of the elements of the line fault diagnostic circuitry to prevent exposure of the at least one of the elements of the line fault diagnostic circuitry to over-voltage caused by the over-voltage line fault.

In an aspect, the over-voltage protection circuitry comprises at least one Zener diode connected between ground and an input voltage pin or input current pin to prevent damage due to the over-voltage line fault.

In an aspect, elements of the over-voltage protection circuitry are configured to redirect current corresponding to the over-voltage line fault away from elements of the line fault protection circuit susceptible to damage caused by the over-voltage line fault.

In an aspect, the over-voltage protection circuitry uses at least one active element and at least one passive element of the over-voltage protection circuitry to control at least another active element of the over-voltage protection circuitry that redirects current away from one or more of the elements of the line fault diagnostic circuitry.

This solution can be scaled to meet any higher voltage battery short protection by changing the external components to have different values to protect the elements of the IC from damage caused by higher battery voltages.

A2B is a bidirectional, high bandwidth digital audio bus that is capable of transporting inter-integrated circuit sound/time division multiplexing/pulse density modulation (I2S/TDM/PDM) data with inter-integrated circuit sound/serial peripheral interface (I2C/SPI) control information, along with clock and power, using a single, 2-wire unshielded twisted pair (UTP) cable over distances up to 15 m between nodes and 80 m over the entire bus length. This bus is well established in automotive applications as well as unified communications applications, and through constant further development, A2B can also be used for many commercial and industrial purposes.

Regarding nomenclature, for A2B, there are main and subordinate (or “sub” in short) nodes.

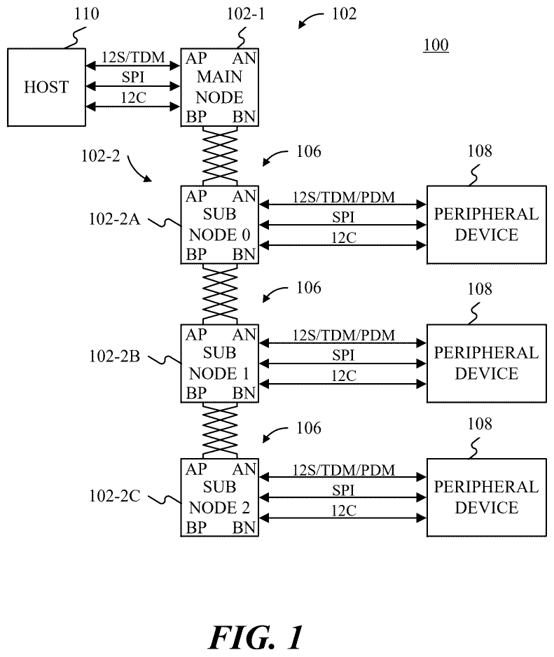

FIG. 1 is a block diagram of an illustrative half-duplex two-wire communication system (hereinafter “system”) 100, such as an A2B network, in accordance with various aspects. The system 100 includes a host 110, a main node 102-1 and at least one sub node 102-2. In FIG. 1, three sub nodes (0, 1, and 2) are illustrated. The depiction of three sub nodes 102-2 in FIG. 1 is simply illustrative, and the system 100 may include one, two, or more sub nodes 102-2, as desired.

The main node 102-1 may communicate with the sub nodes 102-2 over a two-wire bus 106. The bus 106 may include different two-wire bus links between adjacent nodes along the bus 106 to connect the nodes along the bus 106 in a daisy-chain fashion. For example, as illustrated in FIG. 1, the bus 106 may include a link coupling the main node 102-1 to the sub node 0, a link coupling the sub node 0 to the sub node 1, and a link coupling the sub node 1 to the sub node 2. In some aspects, the links of the bus 106 may each be formed of a single twisted-wire pair (e.g., an unshielded twisted pair). In some aspects, the links of the bus 106 may each be formed of a coax cable (e.g., with the core providing the “positive” line and the shield providing the “negative” line, or vice versa). The two-wire bus links together provide a complete electrical path (e.g., a forward and a return current path) so that no additional ground or voltage source lines need be used.

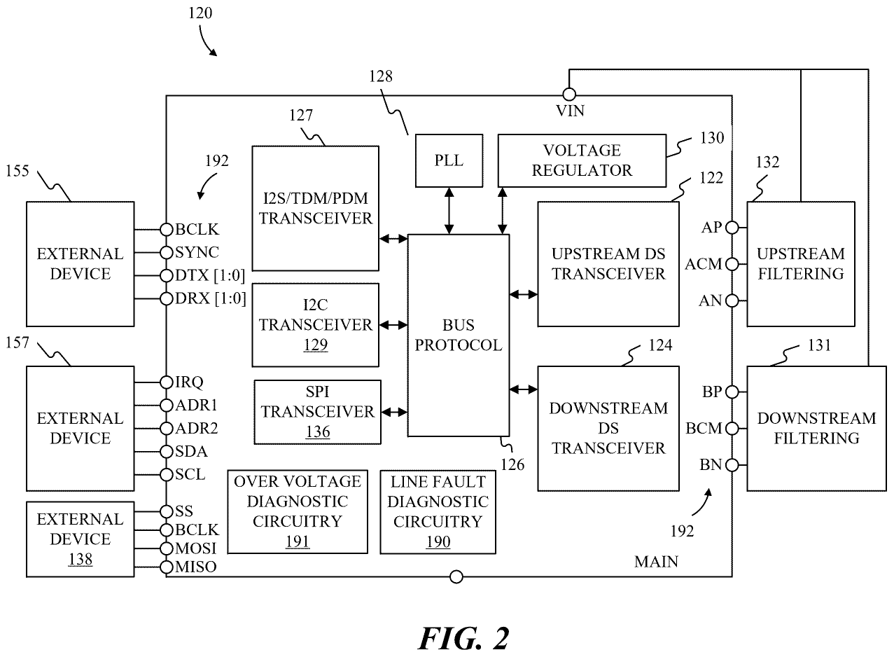

The host 110 may include a processor that programs the main node 102-1, and acts as the originator and recipient of various payloads transmitted along the bus 106. In some aspects, the host 110 may be or may include a microcontroller, for example. In particular, the host 110 may be the master of Inter-Integrated Circuit Sound (I2S) communications that happen along the bus 106. The host 110 may communicate with the main node 102-1 via an I2S/Time Division Multiplex (TDM) protocol, a Serial Peripheral Interface (SPI) protocol, and/or an Inter-Integrated Circuit (I2C) protocol. In some aspects, the main node 102-1 may be a transceiver (e.g., the node transceiver 120 discussed below with reference to FIG. 2) located within a same housing as the host 110. The main node 102-1 may be programmable by the host 110 over the I2C bus for configuration and read-back, and may be configured to generate clock, synchronization, and framing for all the sub nodes 102-2. In some aspects, an extension of the I2C control bus between the host 110 and the main node 102-1 may be embedded in the data streams transmitted over the bus 106, allowing the host 110 direct access to registers and status information for the one or more sub nodes 102-2, as well as enabling I2C-to-I2C communication over distance to allow the host 110 to control the peripheral devices 108. In some aspects, an extension of the SPI control bus between the host 110 and the main node 102-1 may be embedded in the data streams transmitted over the bus 106, allowing the host 110 direct access to registers and status information for the one or more sub nodes 102-2, as well as enabling SPI-to-SPI or SPI-to-I2C communication over distance to allow the host 110 to control the peripheral devices 108. In aspects in which the system 100 is included in a vehicle, the host 110 and/or the main node 102-1 may be included in a headend of the vehicle.

The main node 102-1 may generate “downstream” signals (e.g., data signals, power signals, etc., transmitted away from the main node 102-1 along the bus 106) and receive “upstream” signals (e.g., transmitted toward the main node 102-1 along the bus 106). The main node 102-1 may provide a clock signal for synchronous data transmission over the bus 106. As used herein, “synchronous data” may include data streamed continuously (e.g., audio signals) with a fixed time interval between two successive transmissions to/from the same node along the bus 106. In some aspects, the clock signal provided by the main node 102-1 may be derived from an I2S input provided to the main node 102-1 by the host 110. A sub node 102-2 may be an addressable network connection point that represents a possible destination for data frames transmitted downstream on the bus 106 or upstream on the bus 106. A sub node 102-2 may also represent a possible source of downstream or upstream data frames. The system 100 may allow for control information and other data to be transmitted in both directions over the bus 106 from one node to the next. One or more of the sub nodes 102-2 may also be powered by signals transmitted over the bus 106.

In particular, each of the main node 102-1 and the sub nodes 102-2 may include a positive upstream terminal (denoted as “AP”), a negative upstream terminal (denoted as “AN”), a positive downstream terminal (denoted as “BP”), and a negative downstream terminal (denoted as “BN”). The positive and negative downstream terminals of a node may be coupled to the positive and negative upstream terminals of the adjacent downstream node, respectively. As shown in FIG. 1, the main node 102-1 may include positive and negative upstream terminals, but these terminals may not be used; in other aspects, the main node 102-1 may not include positive and negative upstream terminals. The last sub node 102-2 along the bus 106 (the sub node 2 in FIG. 1) may include positive and negative downstream terminals, but these terminals may not be used; in other aspects, the last sub node 102-2 along the bus may not include positive and negative downstream terminals.

The main node 102-1 may periodically send a synchronization control frame downstream, optionally along with data intended for one or more of the sub nodes 102-2. For example, the main node 102-1 may transmit a synchronization control frame every 1024 bits (representing a superframe) at a frequency of 48 kHz, resulting in an effective bit rate on the bus 106 of 49.152 Mbps. Other rates may be supported, including, for example, 44.1 kHz. The synchronization control frame may allow the sub nodes 102-2 to identify the beginning of each superframe and, in combination with physical layer encoding/signaling, may allow each sub node 102-2 to derive its internal operational clock from the bus 106. The synchronization control frame may include a preamble for signaling the start of synchronization, as well as control fields that allow for various addressing modes (e.g., normal, broadcast, discovery), configuration information (e.g., writing to registers of the sub nodes 102-2), conveyance of I2C information, conveyance of SPI information, remote control of certain general-purpose input/output (GPIO) pins at the sub nodes 102-2, and other services. A portion of the synchronization control frame following the preamble and the payload data may be scrambled in order to reduce the likelihood that information in the synchronization control frame will be mistaken for a new preamble, and to flatten the spectrum of related electromagnetic emissions.

The synchronization control frame may get passed between sub node 102-2 (optionally along with other data, which may come from the main node 102-1 but additionally or alternatively may come from one or more upstream sub nodes 102-2 or from a sub node 102-2 itself) until it reaches the last sub node 102-2 (i.e., the sub node 2 in FIG. 1), which has been configured by the main node 102-1 as the last sub node 102-2 or has self-identified itself as the last sub node 102-2. Upon receiving the synchronization control frame, the last sub node 102-2 may transmit a synchronization response frame followed by any data that it is permitted to transmit (e.g., a 24-bit audio sample in a designated time slot). The synchronization response frame may be passed upstream between sub nodes 102-2 (optionally along with data from downstream sub nodes 102-2), and based on the synchronization response frame, each sub node 102-2 may be able to identify a time slot, if any, in which the sub node 102-2 is permitted to transmit.

In some aspects, one or more of the sub nodes 102-2 in the system 100 may be coupled to and communicate with a peripheral device 108. For example, a sub node 102-2 may be configured to read data from and/or write data to the associated peripheral device 108 using I2S, pulse density modulation (PDM), TDM, SPI, and/or I2C protocols and/or interfaces, as discussed below. Although the “peripheral device 108” may be referred to in the singular herein, this is simply for ease of discussion, and a single sub node 102-2 may be coupled with zero, one, or more peripheral devices. Examples of peripheral devices that may be included in the peripheral device 108 may include a digital signal processor (DSP), a field programmable gate array (FPGA), an application specific integrated circuit (ASIC), an analog to digital converter (ADC), a digital to analog converter (DAC), a codec, a microphone, a microphone array, a speaker, an audio amplifier, a protocol analyzer, an accelerometer or other motion sensor, an environmental condition sensor (e.g., a temperature, humidity, and/or gas sensor), a wired or wireless communication transceiver, a display device (e.g., a touchscreen display), a user interface component (e.g., a button, a dial, or other control), a camera (e.g., a video camera), a memory device, or any other suitable device that transmits and/or receives data. Several examples of different peripheral device configurations are discussed in detail herein.

In some aspects, the peripheral device 108 may include any device configured for I2S communication; the peripheral device 108 may communicate with the associated sub node 102-2 via the I2S protocol. In some aspects, the peripheral device 108 may include any device configured for I2C communication; the peripheral device 108 may communicate with the associated sub node 102-2 via the I2C protocol. In some aspects, the peripheral device 108 may include any device configured for SPI communication; the peripheral device 108 may communicate with the associated sub node 102-2 via the SPI protocol. In some aspects, a sub node 102-2 may not be coupled to any peripheral device 108.

A sub node 102-2 and its associated peripheral device 108 may be contained in separate housings and coupled through a wired or wireless communication connection or may be contained in a common housing. For example, a speaker connected as a peripheral device 108 may be packaged with the hardware for an associated sub node 102-2 (e.g., the node transceiver 120 discussed below with reference to FIG. 2), such that the hardware for the associated sub node 102-2 is contained within a housing that includes other speaker components. The same may be true for any type of peripheral device 108.

As discussed above, the host 110 may communicate with and control the main node 102-1 using multi-channel I2S, SPI, and/or I2C communication protocols. For example, the host 110 may transmit data via I2S to a frame buffer (not illustrated) in the main node 102-1, and the main node 102-1 may read data from the frame buffer and transmit the data along the bus 106. Analogously, the main node 102-1 may store data received via the bus 106 in the frame buffer, and then may transmit the data to the host 110 via I2S.

Each sub node 102-2 may have internal control registers that may be configured by communications from the main node 102-1. Each sub node 102-2 may receive downstream data and may retransmit the data further downstream. Each sub node 102-2 may receive and/or generate upstream data and/or retransmit data upstream and/or add data to and upstream transaction.

Communications along the bus 106 may occur in periodic superframes. Each superframe may begin with a downstream synchronization control frame; be divided into periods of downstream transmission (also called “downstream portions”), upstream transmission (also called “upstream portions”), and no transmission (where the bus 106 is not driven); and end just prior to transmission of another downstream synchronization control frame. The main node 102-1 may be programmed (by the host 110) with a number of downstream portions to transmit to one or more of the sub nodes 102-2 and a number of upstream portions to receive from one or more of the sub nodes 102-2. Each sub node 102-2 may be programmed (by the main node 102-1) with a number of downstream portions to retransmit down the bus 106, a number of downstream portions to consume, a number of upstream portions to retransmit up the bus 106, and a number of upstream portions in which the sub node 102-2 may transmit data received from the sub node 102-2 from the associated peripheral device 108.

Aspects of the communication systems 100 disclosed herein are unique among conventional communication systems in that all sub nodes 102-2 may receive output data over the bus 106 within the same superframe (e.g., all sub nodes 102-2 may receive the same audio sample without sample delays between the nodes 102). In conventional communication systems, data is buffered and processed in each node before being passed downstream in the next frame to the next node. Consequently, in these conventional communication systems, the latency of data transmission depends on the number of nodes (with each node adding a delay of one audio sample). In the communication systems 100 disclosed herein, the bus 106 may only add one cycle of latency, no matter if the first or last sub node 102-2 receives the data. The same is true for upstream communication; data may be available at an upstream node 102 in the next superframe, no matter which sub node 102-2 provided the data.

Further, in aspects of the communication systems 100 disclosed herein, downstream data (e.g., downstream audio data) may be put on the bus 106 by the main node 102-1 or by any of the sub nodes 102-2 that are upstream of the receiving sub node 102-2; similarly, upstream data (e.g., upstream audio data) may be put on the bus 106 by any of the sub nodes 102-2 that are downstream of the receiving node 102 (i.e., the main node 102-1 or a sub node 102-2). Such capability allows a sub node 102-2 to provide both upstream and downstream data at a specific time (e.g., a specific audio sample time). For audio data, this data can be received in the next audio sample at any downstream or upstream node 102 without further delays (besides minor processing delays that fall within the superframe boundary). Control messages (e.g., in a synchronization control frame (SCF)) may travel to the last node 102 (addressing a specific node 102 or broadcast) and an upstream response (e.g., in a synchronization response frame (SRF)) may be created by the last downstream node 102 within the same superframe. Nodes 102 that have been addressed by the SCF change the content of the upstream SRF with their own response. Consequently, within the same audio sample, a control and a response may be fully executed over multiple nodes 102. This is also in contrast to conventional communication systems, in which sample latencies would be incurred between nodes (for relaying messages from one node to the other).

Each of the main node 102-1 and the sub nodes 102-2 may include a transceiver to manage communication between components of the system 100.

FIG. 2 is a block diagram of a node transceiver 120 that may be included in a node (e.g., the main node 102-1 or a sub node 102-2) of the system 100 of FIG. 1, in accordance with various aspects. In some aspects, a node transceiver 120 may be included in each of the nodes of the system 100, and a control signal may be provided to the node transceiver 120 via a main (MAIN) pin to indicate whether the node transceiver 120 is to act as a main node (e.g., when the MAIN pin is high) or a sub node (e.g., when the MAIN pin is low).

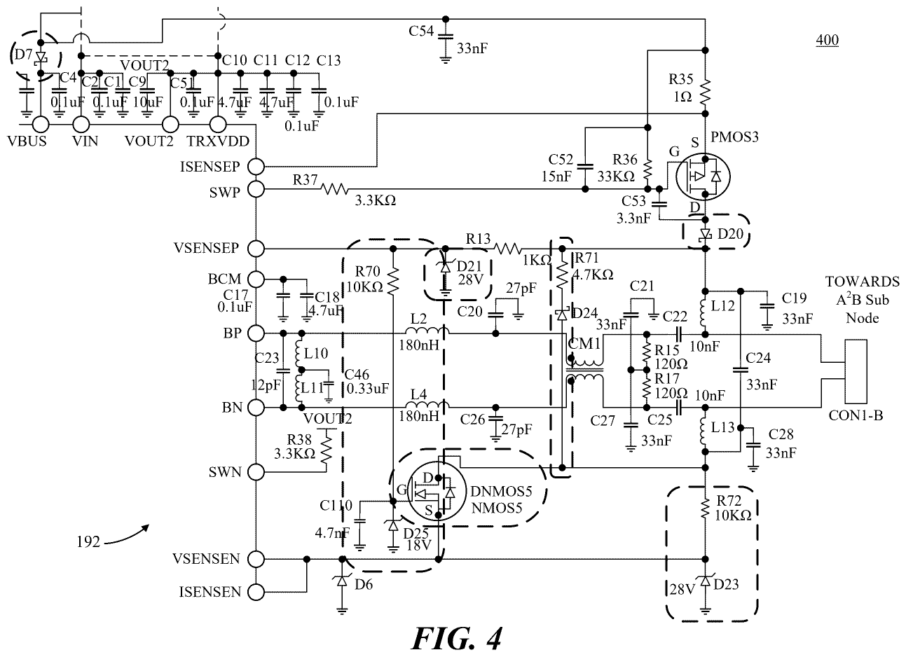

The node transceiver 120 may include line fault diagnostic circuitry 190 configured to detect and classify line faults in the network. The line fault diagnostic circuitry 190 may be connected to a bus, which, in turn, is connected to a plurality of pins 192 of the node transceiver 120, some of which are shown in FIG. 2, and others in FIGS. 4-8 and 10. In another aspect, the line fault diagnostic circuitry 190 is directly connected to each of the plurality of pins 192.

In particular, the line fault diagnostic circuitry 190 is configured to detect and classify line faults on the plurality of pins 192. For example, the line fault diagnostic circuitry 190 may detect and classify an over-voltage line fault on one or more of the plurality of pins 192. The line fault diagnostic circuitry 190 detects and classifies line faults on the plurality of pins 192 by measuring and analyzing voltage and current signals on at least some of the plurality of pins 192. For example, pins that directly receive current or voltage inputs may be included in a set of pins that are monitored by the line fault diagnostic circuitry 190. In another aspect, pins that directly receive current or voltage inputs and pins that are connected to such current or voltage receiving pins may be included in a set of pins that are monitored by the line fault diagnostic circuitry 190. In an aspect, a measured value on a pin is compared to a reference voltage, e.g., by a comparator. In an aspect, a measured value on a pin is analyzed with respect to a reference voltage, e.g., by a summing amplifier and/or a difference amplifier to see if a sum or a difference is greater than a threshold (reference) value.

In an aspect, the line fault diagnostic circuitry 190 may include a first set of elements including resistors, capacitors, summing amplifiers, difference amplifiers, operational amplifiers, comparators and other devices for use in comparing the current entering and leaving a protected section of a target line being monitored or a voltage level of a target line being monitored. The preceding are but a few of the types of active and passive elements that may be used by the line fault diagnostic circuitry 190 to detect and/or classify line faults occurring in the node transceiver 120.

In an aspect, the line fault diagnostic circuitry 190 may be configured to detect and classify, for example, but not limited to, open circuit faults, short circuit faults, and over-voltage faults. An open circuit fault typically occurs when a conductor breaks. An open circuit fault disrupts the flow of current. A short circuit fault is an electrical circuit fault that allows a current to travel along an unintended path with no or very low electrical impedance. Short circuits can include shorts between different conductors or lines and/or between a conductor or line and ground. A short circuit fault typically results from the unintended contact of conductor and/or components and consequential accidental diversion of current. An over-voltage fault occurs when a higher voltage than usually a maximum operating voltage is applied to an unintended element. An over-voltage fault can permanently damage both active and passive elements of the node transceiver 120 including those forming the line fault diagnostic circuitry 190 rendering them unusable thereafter. An over-voltage fault can be caused by power supply issues such as a power supply delivering a voltage exceeding the IC's rated maximum (where the IC's rated voltage maximum may be represented by a reference voltage against which a pin voltage is compared), a transient voltage event, for example, caused by a switching circuit, and internal circuit failures such as fault components with the IC such as, for example, but not limited to, damaged transistors, broken connections, and so forth.

The node transceiver 120 may include over-voltage protection circuitry 191 configured to protect the plurality of pins 192 and the line fault diagnostic circuitry 190 of the IC from the over-voltage line fault by applying over-voltage compensation techniques including voltage reduction and voltage avoidance to the plurality of pins 192 and the line fault diagnostic circuitry 190. In an aspect, the over-voltage protection circuitry 191 is connected to the plurality of pins 192 and the line fault diagnostic circuitry 190. In an aspect, the over-voltage protection circuitry 191 includes a second set of elements that, in turn, include active elements and passive elements, configured to protect the plurality of pins 192 and the line fault diagnostic functionality of the IC from an over-voltage line fault that exceeds a maximum voltage threshold of at least the plurality of pins 192.

In an aspect, the over-voltage protection circuitry 191 is configured to protect the plurality of pins 192 and the fault diagnostic circuitry 190 of the IC from the over-voltage line fault by reducing an amount of voltage the plurality of pins 192 are exposed to during the over-voltage line fault to be less than the maximum voltage threshold of at least the plurality of pins 192.

In an aspect, the over-voltage protection circuitry 191 is configured to protect the plurality of pins 192 and the line fault diagnostic circuitry 190 of the IC from the over-voltage line fault by turning off, during the over-voltage line fault, any of the active elements of the line fault diagnostic circuitry 190 that are susceptible to over-voltage damage.

In an aspect, the over-voltage protection circuitry 191 is configured to protect the plurality of pins 192 and the line fault diagnostic circuitry 190 of the IC from the over-voltage line fault by controlling at least one of the active elements of the over-voltage protection circuitry 191 to alter a current path in the IC used by at least one of the elements of the line fault diagnostic circuitry 190 to prevent exposure of the at least one of the elements of the line fault diagnostic circuitry 190 to over-voltage caused by the over-voltage line fault.

In an aspect, the over-voltage protection circuitry 191 comprises at least one Zener diode connected between ground and an input voltage pin or input current pin to prevent damage due to the over-voltage line fault.

In an aspect, elements of the over-voltage protection circuitry 191 are configured to redirect current corresponding to the over-voltage line fault away from elements of the line fault diagnostic circuitry 190 susceptible to damage caused by the over-voltage line fault. This may involve opening a path that is normally closed, and/or closing a path that is normally open. For example, one or more transistors may be controlled to redirect current in the event of an over-voltage fault.

In an aspect, the over-voltage protection circuitry 191 uses at least one active element and at least one passive element of the over-voltage protection circuitry 191 to control at least another active element of the over-voltage protection circuitry 191 that redirects current away from one or more of the elements of the line fault diagnostic circuitry.

In an aspect, various pins from among the plurality of pins 192 are also part of the line fault diagnostic circuitry 190 in that the pins initially receive voltage or current to identify over-voltage, open circuit, and/or short circuit faults.

The node transceiver 120 may include an upstream differential signaling (DS) transceiver 122 and a downstream DS transceiver 124. The upstream DS transceiver 122 may be coupled to the positive and negative upstream terminals discussed above with reference to FIG. 1, and the downstream DS transceiver 124 may be coupled to the positive and negative downstream terminals discussed above with reference to FIG. 1. In some aspects, the upstream DS transceiver 122 may be a low voltage DS (LVDS) transceiver, and the downstream DS transceiver 124 may be an LVDS transceiver. Each node in the system 100 may be AC-coupled to the bus 106, and data signals may be conveyed along the bus 106 (e.g., via the upstream DS transceiver 122 and/or the downstream DS transceiver 124) using a predetermined form of DS (e.g., LVDS or Multipoint LVDS (MLVDS) or similar signaling) with appropriate encoding to provide timing information over the bus 106 (e.g., differential Manchester coding, bi-phase mark coding, Manchester coding, Non-Return-to-Zero, Inverted (NRZI) coding with run-length limiting, or any other suitable encoding).

The upstream DS transceiver 122 and the downstream DS transceiver 124 may communicate with bus protocol circuitry 126, and the bus protocol circuitry 126 may communicate with a phased locked loop (PLL) 128 and voltage regulator circuitry 130, among other components. When the node transceiver 120 is powered up, the voltage regulator circuitry 130 may raise a “power good” signal that is used by the PLL 128 as a power-on reset.

As noted above, one or more of the sub nodes 102-2 in the system 100 may receive power transmitted over the bus 106 concurrently with data. For power distribution (which is optional, as some of the sub nodes 102-2 may be configured to have exclusively local power provided to them), the main node 102-1 may place a DC bias on the bus link between the main node 102-1 and the sub node 0 (e.g., by connecting, through a low-pass filter, one of the downstream terminals to a voltage source provided by a voltage regulator and the other downstream terminal to ground). The DC bias may be a predetermined voltage, such as 5 volts, 8 volts, the voltage of a car battery, or a higher voltage (e.g., 48V). Each successive sub node 102-2 can selectively tap its upstream bus link to recover power (e.g., using the voltage regulator circuitry 130). This power may be used to power the sub node 102-2 itself (and optionally one or more peripheral device 108 coupled to the sub node 102-2). A sub node 102-2 may also selectively bias the bus link downstream for the next-in-line sub node 102-2 with either the recovered power from the upstream bus link or from a local power supply. For example, the sub node 0 may use the DC bias on the upstream link of the bus 106 to recover power for the sub node 0 itself and/or for one or more associated peripheral device 108, and/or the sub node 0 may recover power from its upstream link of the bus 106 to bias its downstream link of the bus 106.

Thus, in some aspects and additionally referring to FIG. 1, each node in the system 100 may provide power to the following downstream node over a downstream bus link. The powering of nodes may be performed in a sequenced manner. For example, after discovering and configuring the sub node 0 via the bus 106, the main node 102-1 may instruct the sub node 0 to provide power to its downstream link of the bus 106 in order to provide power to the sub node 1; after the sub node 1 is discovered and configured, the main node 102-1 may instruct the sub node 1 to provide power to its downstream link of the bus 106 in order to provide power to the sub node 2 (and so on for additional sub nodes 102-2 coupled to the bus 106). In some aspects, one or more of the sub nodes 102-2A, 102-2B or 102-2C may be locally powered, instead of or in addition to being powered from its upstream bus link. In some such aspects, the local power source for a given sub node 102-2 may be used to provide power to one or more downstream sub nodes.

In some aspects, upstream bus interface circuitry 132 may be disposed between the upstream DS transceiver 122 and the voltage regulator circuitry 130, and downstream bus interface circuitry 131 may be disposed between the downstream DS transceiver 124 and the voltage regulator circuitry 130. Since each link of the bus 106 may carry alternating current (AC) (signal) and direct current (DC) (power) components, the upstream bus interface circuitry 132 and the downstream bus interface circuitry 131 may separate the AC and DC components, providing the AC components to the upstream DS transceiver 122 and the downstream DS transceiver 124, and providing the DC components to the voltage regulator circuitry 130. AC couplings on the line side of the upstream DS transceiver 122 and downstream DS transceiver 124 substantially isolate the upstream DS transceiver 122 and downstream DS transceiver 124 from the DC component on the line to allow for high-speed bi-directional communications. As discussed above, the DC component may be tapped for power, and the upstream bus interface circuitry 132 and the downstream bus interface circuitry 131 may include a ferrite, a common mode choke, or an inductor, for example, to reduce the AC component provided to the voltage regulator circuitry 130. In some aspects, the upstream bus interface circuitry 132 may be included in the upstream DS transceiver 122, and/or the downstream bus interface circuitry 131 may be included in the downstream DS transceiver 124; in other aspects, the filtering circuitry may be external to the upstream DS transceiver 122 and downstream DS transceiver 124.

The node transceiver 120 may include a transceiver 127 for I2S, TDM, and PDM communication between the node transceiver 120 and an external device 155. Although the “external device 155” may be referred to in the singular herein, this is simply for ease of illustration, and multiple external devices may communicate with the node transceiver 120 via the I2S/TDM/PDM transceiver 127. The I2S protocol is for carrying pulse code modulated (PCM) information (e.g., between audio chips on a printed circuit board (PCB)). As used herein, “I2S/TDM” may refer to an extension of the I2S stereo (2-channel) content to multiple channels using TDM. PDM may be used in sigma delta converters, and in particular, PDM format may represent an over-sampled 1-bit sigma delta ADC signal before decimation. PDM format is often used as the output format for digital microphones. The I2S/TDM/PDM transceiver 127 may be in communication with the bus protocol circuitry 126 and pins for communication with the external device 155. Six pins, BCLK, SYNC, DTX[1:0], and DRX[1:0], are illustrated in FIG. 2; the BCLK pin may be used for an I2S bit clock, the SYNC pin may be used for an I2S frame synchronization signal, and the DTX[1:0] and DRX[1:0] pins are used for transmit and receive data channels, respectively. Although two transmit pins (DTX[1:0]) and two receive pins (DRX[1:0]) are illustrated in FIG. 2, any desired number of receive and/or transmit pins may be used.

When the node transceiver 120 is included in the main node 102-1, the external device 155 may include the host 110, and the I2S/TDM/PDM transceiver 127 may provide an I2S subordinate (regarding BCLK and SYNC) that can receive data from the host 110 and send data to the host 110 synchronously with an I2S interface clock of the host 110. In particular, an I2S frame synchronization signal may be received at the SYNC pin as an input from the host 110, and the PLL 128 may use that signal to generate clocks. When the node transceiver 120 is included in a sub node 102-2, the external device 155 may include one or more peripheral devices 108, and the I2S/TDM/PDM transceiver 127 may provide an I2S clock master (for BCLK and SYNC) that can control I2S communication with the peripheral device 108. In particular, the I2S/TDM/PDM transceiver 127 may provide an I2S frame synchronization signal at the SYNC pin as an output. Registers in the node transceiver 120 may determine which and how many I2S/TDM channels are being transmitted as data slots over the bus 106. A TDM mode (TDMMODE) register in the node transceiver 120 may store a value of how many TDM channels fit between consecutive SYNC pulses on a TDM transmit or receive pin. Together with knowledge of the channel size, the node transceiver 120 may automatically set the BCLK rate to match the number of bits within the sampling time (e.g., 48 kHz).

The node transceiver 120 may include a transceiver 129 for I2C communication between the node transceiver 120 and an external device 157. Although the “external device 157” may be referred to in the singular herein, this is simply for ease of illustration, and multiple external devices may communicate with the node transceiver 120 via the I2C transceiver 129. The I2C protocol uses clock (SCL) and data (SDA) lines to provide data transfer. The I2C transceiver 129 may be in communication with the bus protocol circuitry 126 and pins for communication with the external device 157. Four pins, ADR1, ADR2, SDA, and SCL are illustrated in FIG. 2; ADR1 and ADR2 may be used to modify the I2C addresses used by the node transceiver 120 when the node transceiver 120 acts as an I2C slave (e.g., when it is included in the main node 102-1), and SDA and SCL are used for the I2C serial data and serial clock signals, respectively. When the node transceiver 120 is included in the main node 102-1, the external device 157 may include the host 110, and the I2C transceiver 129 may provide an I2C slave that can receive programming instructions from the host 110. In particular, an I2C serial clock signal may be received at the SCL pin as an input from the host 110 for register accesses. When the node transceiver 120 is included in a sub node 102-2, the external device 157 may include a peripheral device 108 and the I2C transceiver 129 may provide an I2C master to allow the I2C transceiver to program one or more peripheral devices in accordance with instructions provided by the host 110 and transmitted to the node transceiver 120 via the bus 106. In particular, the I2C transceiver 129 may provide the I2C serial clock signal at the SCL pin as an output.

The node transceiver 120 may include a transceiver 136 for SPI communication between the node transceiver 120 and an external device 138. Although the “external device 138” may be referred to in the singular herein, this is simply for ease of illustration, and multiple external devices may communicate with the node transceiver 120 via the SPI transceiver 136. The SPI protocol uses slave select (SS), clock (BCLK), master-out-slave-in (MOSI), and master-in-slave-out (MISO) data lines to provide data transfer, and pins corresponding to these four lines are illustrated in FIG. 2. The SPI transceiver 136 may be in communication with the bus protocol circuitry 126 and pins for communication with the external device 138. When the node transceiver 120 is included in the main node 102-1, the external device 138 may include the host 110 or another external device, and the SPI transceiver 136 may provide an SPI slave that can receive and respond to commands from the host 110 or other external device. When the node transceiver 120 is included in a sub node 102-2, the external device 138 may include a peripheral device 108 and the SPI transceiver 136 may provide an SPI host to allow the SPI transceiver 136 to send commands to one or more peripheral devices 108. The SPI transceiver 136 may include a read data first-in-first-out (FIFO) buffer and a write data FIFO buffer. The read data FIFO buffer may be used to collect data read from other nodes 102, and may be read by an external device 138 when the external device 138 transmits an appropriate read command. The write data FIFO buffer may be used to collect write data from the external device 138 before the write data is transmitted to another device.

The node transceiver 120 may include an interrupt request (IRQ) pin in communication with the bus protocol circuitry 126. When the node transceiver 120 is included in the main node 102-1, the bus protocol circuitry 126 may provide event-driven interrupt requests toward the host 110 via the IRQ pin. When the node transceiver 120 is included in a sub node 102-2 (e.g., when the MSTR pin is low), the IRQ pin may serve as a GPIO pin with interrupt request capability. The node transceiver 120 may include other pins in addition to those shown in FIG. 2.

The system 100 may operate in any of a number of different operational modes. The nodes on the bus 106 may each have a register indicating which operational mode is currently enabled. Descriptions follow of examples of various operational modes that may be implemented. In a standby operational mode, bus activity is reduced to enable global power savings; the only traffic required is a minimal downstream preamble to keep the PLLs of each node (e.g., the PLL 128) synchronized. In standby operational mode, reads and writes across the bus 106 are not supported. In a discovery operational mode, the main node 102-1 may send predetermined signals out along the bus 106 and wait for suitable responses to map out the topology of sub nodes 102-2 distributed along the bus 106. In a normal operational mode, full register access may be available to and from the sub nodes 102-2 as well as access to and from peripheral devices 108 over the bus 106. Normal mode may be globally configured by the host 110 with or without synchronous upstream data and with or without synchronous downstream data.

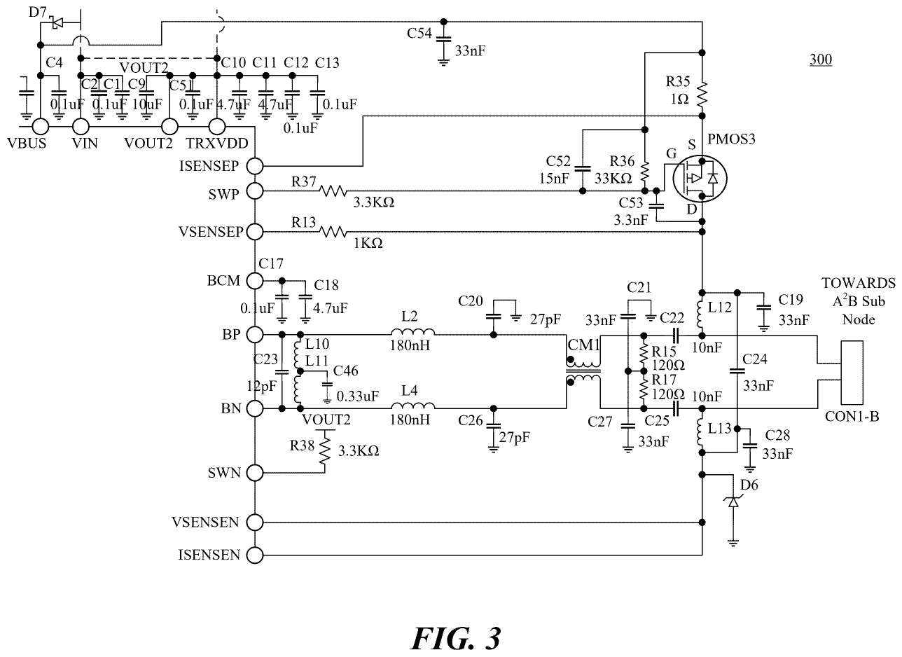

Referring to FIG. 3, conventional bus bias circuitry 300 for an A2B main node is shown.

Bus bias circuitry 300 uses a high-side p-channel field effect transistor (PFET) switch controlled by SWP pin and an internal n-channel field effect transistor (NFET) switch (not shown) to send the bus bias. Prior to turning on the switches and during operation, a transceiver (such as node transceiver 120 of FIG. 2) senses the line for various faults and automatically turns off the FETs.

After detecting the fault, the transceiver updates the switch status register and generates an interrupt to indicate about the fault.

Bus bias circuitry 300 includes the following elements for performing the following functions:

Resistor R35 is a current limiting resistor which limits the current during faults and prevents the p-channel metal oxide semiconductor field effect transistor (“PMOSFET3” or “PMOS3” in short) PFET PMOS3 from being exposed to over current. RC filters (e.g., C52 and R36), connected between the gate of PFET PMOS3 and pin SWP, control the current during initialization by slowing down the turning on of the PFET PMOS3. Series resistors R37 and R13 on the SWP and VSENSEP pins, respectively, limit the input current to these pins. Transient voltage suppression (TVS) diode D6 protects the VSESNEN and ISENSEN pins from the transients associated with electrostatic discharge (ESD).

A description of the remaining elements of FIG. 3 will now be given:

C4 is a decoupling capacitor on the VBUS pin;

C1, C2 are decoupling capacitors on the VIN pin;

C9, C51, C10, C11, C12, C13 are decoupling capacitors present on the VOUT2 net as well as the TRXVDD pins of the transceiver;

D7 acts as a reverse blocking diode to stop high voltage faults on CON1-B from reaching the VIN pin;

C54 is a bypass capacitor that helps in bypassing the transients from CON1-B, PMOS-3 body diode, and R35;

R35 is a current limiting resistor;

C53 is a filter capacitor that helps in slowing down the turn ON and Turn OFF of the PMOS3;

C17, C18 are decoupling capacitors on the BCM pins;

R38 is a pullup resistor on the SWN pin;

C19, L12, C28, L13 act as an LC filter to provide high impedance to high frequency communication signals;

C22, C25 act as DC blocking capacitors and allow AC signals to reach the BP, BN pins;

R15, R17, C21, C27 form a termination network;

CM1 blocks the common mode noise from entering the A2B transceiver pins;

C23, L2, C20, L4, C26 form a low pass filter to filter high frequencies to and from the transceiver; and

L10, L11, C46 form a notch filter intended to suppress very low frequencies.

Limitation of bus bias circuitry 300: Short to battery faults (with a 48V battery) will cause integrated circuit (IC) pins V/ISENSEP, V/ISENSEN, SWP and VBUS to see greater than 30V, which is beyond the AMVR of these pins and can thus cause damage to the chip.

Referring to FIGS. 4-8, respective bus bias circuitries 400, 500, 600, 700, and 800 are shown for B-port of an A2B main or local powered sub (LPS) node. The B-port of the A2B LPS node is an A2B transceiver interface of the A2B LPS node that faces towards a next subordinate or A2B LPS node in a network that includes a main node and one or more subordinate or LPS nodes that serve the main node (by following requests issued by the main node).

Bus bias circuitries 400 and 500 correspond to a first solution provided by the present disclosure relating to a first implementation of the over-voltage protection circuitry 191, bus bias circuitry 600 corresponds to a second solution provided by the present disclosure relating to a version of the first implementation of the over-voltage protection circuitry 191, bus bias circuitry 700 corresponds to a third solution provided by the present disclosure relating to a third implementation of the over-voltage protection circuitry 191, and bus bias circuitry 800 corresponds to a fourth solution provided by the present disclosure relating to a fourth implementation of the over-voltage protection circuitry 191. All of the solutions are related in that they are based on many common elements from bus bias circuitry 400 corresponding to the first solution. The differences between the respective bus bias circuitries 400, 500, 600, 700, and 800 are described below.

In FIGS. 4-8, dashed lines indicate items that have been newly added to the bus bias circuitries 400, 500, 600, 700, and 800 or moved to a different position in the bus bias circuitries 400, 500, 600, 700, and 800. The bus bias circuitries 400, 500, 600, 700, and 800 are different versions of the over-voltage protection circuit 191.

Referring to FIG. 4, example bus bias circuitry 400 is shown, in accordance with an exemplary aspect. Bus bias circuitry 400 corresponds to an implementation of the over-voltage protection circuit 191 relating to a first solution.

Bus bias circuitry 400 includes an integrated circuit (IC) including at least the following pins. The pins are described with respect to A2B transceivers which are used to send audio data over a single twisted pair cable. While A2B transceivers are used to describe various aspects of the present disclosure, it is to be appreciated that the present disclosure can be applied to other transceivers in general including non-A2B transceivers and also other IC types (e.g., non-transceivers). For example, aspects of the present disclosure can be applied to any integrated circuit to protect the IC circuitry from over-voltage while at the same time preserving the functionality of the line fault diagnostic capabilities of the IC. To that end, various elements are used hereinafter to, for example, minimize a voltage to which elements are exposed or redirect current away from elements that can be damaged to protect IC pins and also line fault diagnostic capabilities of the IC.

The following are at least some of the plurality of pins 192 protected by the over-voltage protection circuitry 191.
SWP—this pin controls the gate of high-side switch (PMOS3)
VSENSEP—this pin senses the high-side line voltage
ISENSEP 0—used for diagnostic purposes
VSENSEN—this pin senses the low-side line voltage and provides the path to return current via an internal NMOS switch
ISENSEN—used for diagnostic purposes
VIN—this is power supply input pin
VBUS—input pin to sense the bus-bias voltage
VOUT2—on chip low drop-out regulator, generating typical output of the order of 3.3V which is used to power transceiver supply pins and other peripherals.
TRXVDD—Power supply pin for A2B line driver and receiver circuit,
BCM—Common-mode input for bidirectional, differential A2B line transceiver B.
BP—Noninverted pin of bidirectional, differential A2B line driver and receiver B. It is directed towards the next downstream subordinate transceiver on the A2B bus.
BN—Inverted pin of bidirectional, differential A2B line driver and receiver B. It is directed towards the next downstream subordinate transceiver on the A2B bus.

SWN—this pin is used to detect the hardware configuration of the bus-bias circuitry connected to the transceiver.

Of the preceding pins, the following listing are of pins that part of the plurality of pins 192 and also part of the line fault diagnostic circuitry 190: VSENSEP, ISENSEP, VSENSEN, ISENSEN, SWP, and SWN.

By having some pins being part of the line fault diagnostic circuit 190, shielding those pins from over-voltage will also shield the elements of the line fault diagnostic circuit 190 connected to those pins. Thus, over-voltage protection circuitry 191 performs dual duty in protecting both plurality of pins 192 and line fault diagnostic circuitry 190 and hence the line fault diagnostic functionality of the IC. That is, the protection of plurality of pins 192 and line fault diagnostic circuitry 190 from an over-voltage fault results in the protection of the line fault diagnostic functionality of the IC from the over-voltage fault. In this way, the normal functionality of the IC, including the line fault diagnostic functionality of line fault diagnostic circuitry 190, can be preserved despite the application of the over-voltage fault for a period of time.

During short to battery fault events, the VSENSEP/VSENSEN pins of bus bias circuitry 400 will be exposed to battery voltages.

Bus bias circuitry 400 is configured to protect the VSENSEP, ISENSEP, VSENSEN, ISENSEN, and other IC pins from over-voltage. In dashed line, referring to configuration 405, bus bias circuitry 400 includes a Schottky diode D20 to prevent the back propagation of battery voltage beyond the VSENSEP pin to any of the VBUS, ISENSEP, or SWP pins.

In dashed line, referring to configuration 406, bus bias circuitry 400 includes an n-channel metal oxide semiconductor field effect transistor (“NMOSFET5” or “NMOS5” in short) as a series switch to break the current path during battery faults. In dashed line, referring to configuration 407, Resistor R70, Diode D25, and capacitor C110 control the gate of NMOS5 and limit the gate voltage of NMOS5 to prevent VSENSEN and ISENSEN from being exposed to over-voltage during an over-voltage fault. When the NMOS5 is switching power through an inductive load, there will be a time at device turn-off when the field in the load will collapse and drive a current back through NMOS5. Diode DNMOS5 is an intrinsic (body) diode of NMOS5.

In dashed line, respectively referring to configurations 403 and 407, 28V Zener diodes D21 and D23 are added to limit the voltages on the VSENSEP and VSENSEN pins below 30V which is the Absolute Max Voltage Rating of the VSENSEP and VSENSEN pins.

Further, 1k series resistor (R13) is sized to survive the over-voltages. Configuration 407 also helps in turning off the NMOS5 during battery faults.

In dashed line, referring to configuration 404, Diode D24 and resistor R71 helps in diagnosing the short to battery fault.

In dashed line, referring to configuration 401, in bus bias circuitry 400, the position of Diode D7 is changed so that the line fault diagnostic function of IC works properly at lower input voltages also.

For convention sake, the pins connected to the positive battery side are referred to as being on the “high side,” and the pins connected to the negative battery side are referred to as being on the “low side.”

For the high side, Schottky diode D20 is configured to protect all the pins above the VSENSEP pin from back propagation of a short to battery fault. The protected pins above the VSENSEP pin include: VBUS; ISENSEP; and SWP. Moreover, Zener diode D21 is configured to protect the VSENSEP pin from over-voltage due to a short to battery fault so that the VSENSEP pin never sees a voltage above its AMVR but still senses the line for battery faults.

For the low side, NMOS5 is configured as a series switch to protect the pins above the VSENSEN pin. The gate of NMOS5 is controlled by the VSENSEP pin. Resistor R72 and Diode D23 are configured to have a dual functionality of protecting the VSENSEN and ISENSEN pins and turning off NMOS5 in case of any short to battery event.

To protect the line fault diagnostic feature, a resistor R71 is placed in series to form a series combination with a diode D24, with a resistor end of the series combination connected to the VSENSEP pin, and a diode end of the series combination connection connected to the VSENSEN pin through resistor R72 and also to a non-gate terminal of the NMOS5.

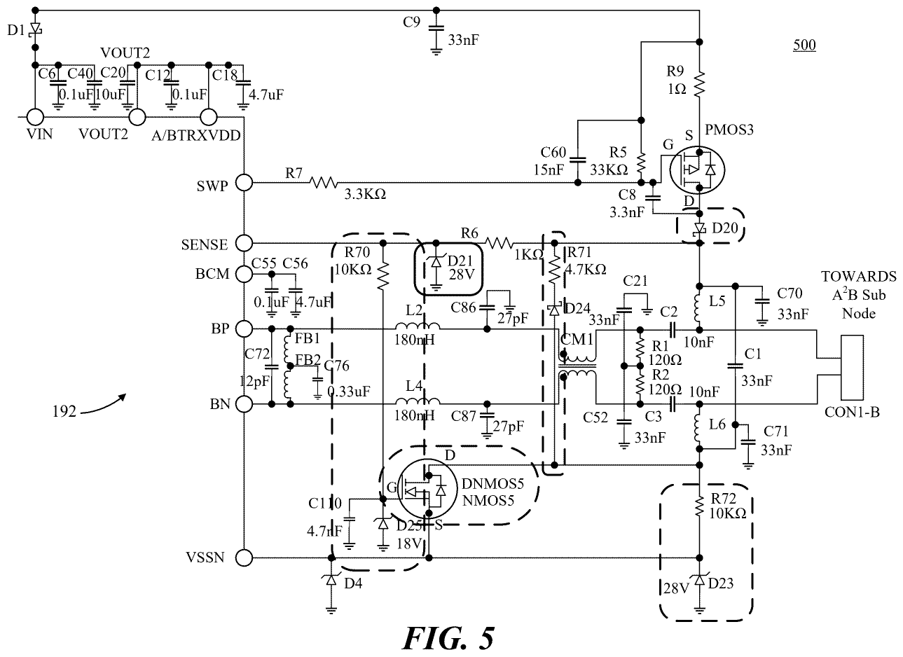

Referring to FIG. 5, example bus bias circuitry 500 is shown, in accordance with an exemplary aspect. Bus bias circuitry 500 corresponds to an implementation of the over-voltage protection circuit 191 relating to another version of the first solution of the present disclosure. Bus bias circuitry 500 is described with respect to bus bias circuitry 400 of FIG. 4. Accordingly, the following description of bus bias circuitry 500 is directed to differences between bus bias circuitry 500 and bus bias circuitry 400 of FIG. 4.

In bus bias circuitry 500, cathode of Diode D7 is not further connected to the VIN and TRXVDD pins, unlike in bus bias circuitry 400 of FIG. 4.

The remaining circuitry of bus bias circuitry 500 remains the same as described with respect to bus bias circuitry 400 of FIG. 4 and the first solution.

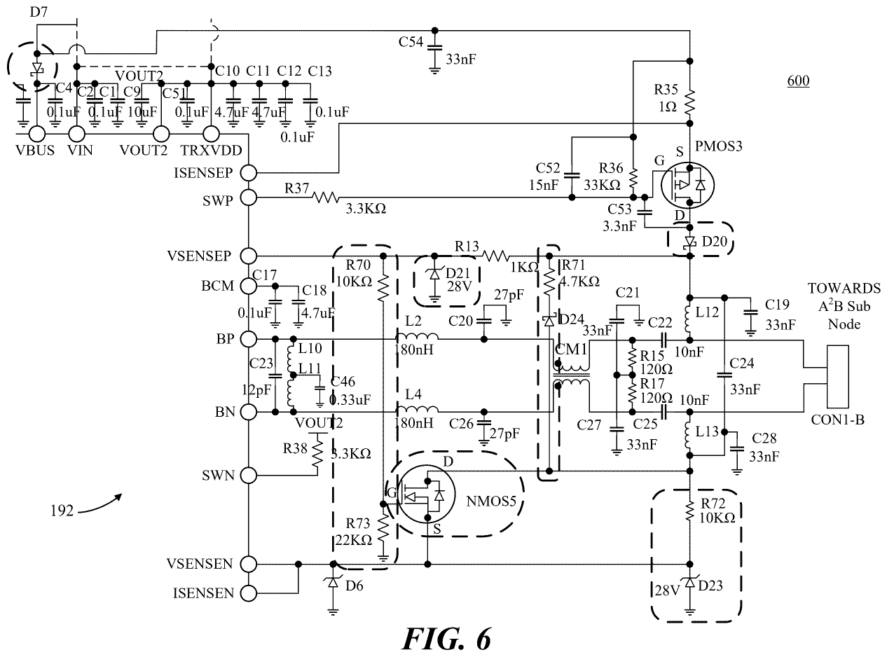

Referring to FIG. 6, example bus bias circuitry 600 is shown, in accordance with an exemplary aspect. Bus bias circuitry 600 corresponds to an implementation of the over-voltage protection circuit 191 relating to a second solution of the present disclosure. Bus bias circuitry 600 is described with respect to bus bias circuitry 400 of FIG. 4. Accordingly, the following description of bus bias circuitry 600 is directed to differences between bus bias circuitry 600 and bus bias circuitry 400 of FIG. 4.

Instead of using Zener diode D25 on the gate of NMOS5, a resistor divider can be used on the gate of NMOS5 by including resistor R73 in series with resistor R70, with a midpoint of the resistor divider connected to the gate of NMOS5, the other side of resistor R73 connected to VSENSEN, and the other side of R70 connected to VSENSEP. In an aspect, the resistor values of resistor R73 and resistor R70 are selected to limit the gate voltage of NMOS5. In an aspect, resistor R73 is equal to 22 kΩ, and resistor R70 is equal to 10 KΩ.

The remaining circuitry of bus bias circuitry 600 remains the same as described with respect to bus bias circuitry 400 of FIG. 4 and the first solution.

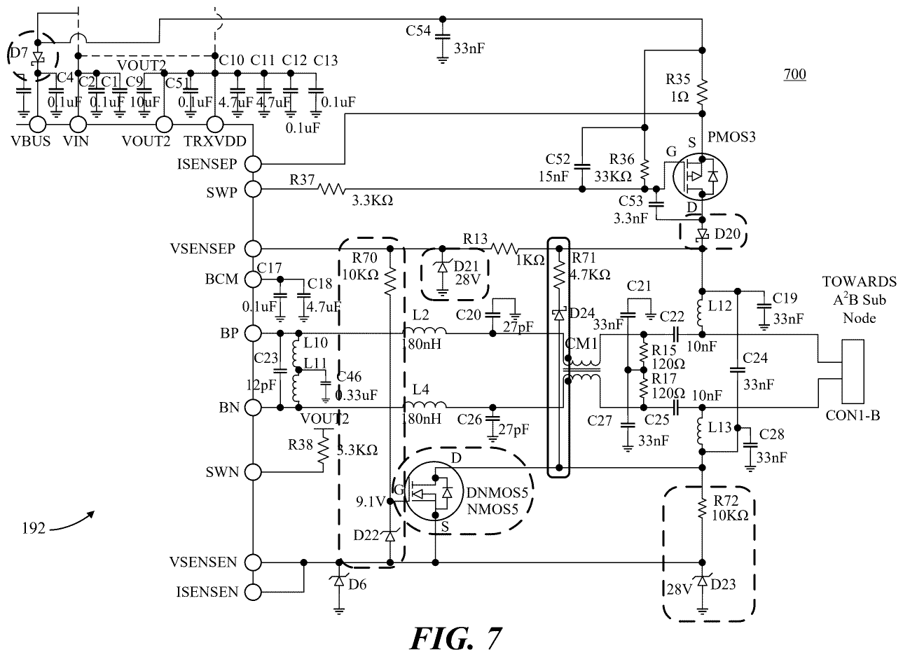

Referring to FIG. 7, example bus bias circuitry 700 is shown, in accordance with an exemplary aspect. Bus bias circuitry 700 corresponds to an implementation of the over-voltage protection circuit 191 relating to a third solution of the present disclosure. Bus bias circuitry 700 is described with respect to bus bias circuitry 400 of FIG. 4. Accordingly, the following description of bus bias circuitry 700 is directed to differences between bus bias circuitry 700 and bus bias circuitry 400 of FIG. 4.

In bus bias circuitry 700, Zener diode D22 is connected between a gate and a source of NMOS5.

The remaining circuitry of bus bias circuitry 700 remains the same as described with respect to bus bias circuitry 400 of FIG. 4 and the first solution.

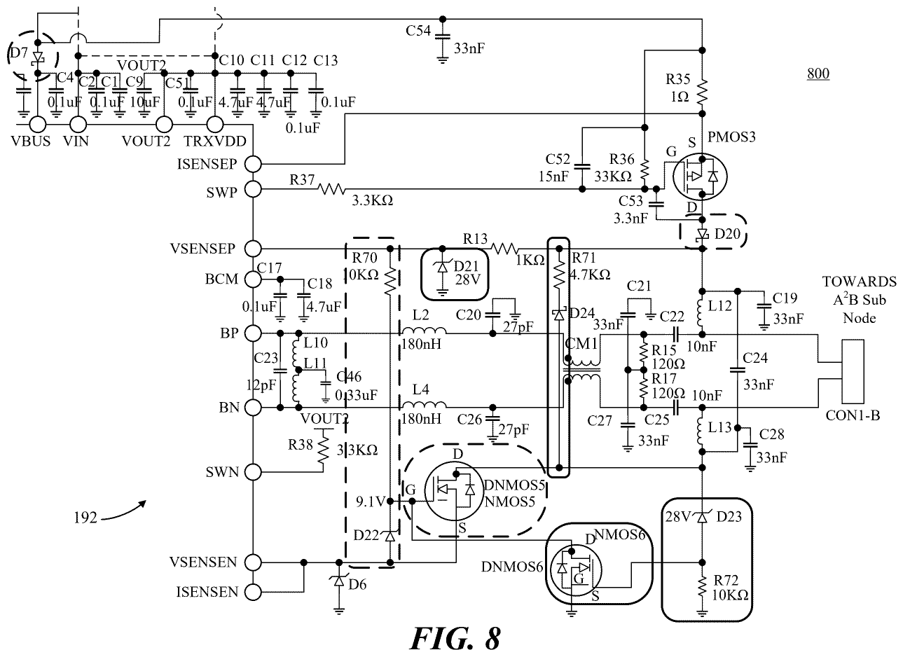

Referring to FIG. 8, example bus bias circuitry 800 is shown, in accordance with an exemplary aspect. Bus bias circuitry 800 corresponds to an implementation of the over-voltage protection circuit 191 relating to a fourth solution of the present disclosure that is most similar to bus bias circuitry 700 corresponding to the third solution. Bus bias circuitry 800 is described with respect to bus bias circuitry 700 of FIG. 7. Accordingly, the following description of bus bias circuitry 800 is directed to differences between bus bias circuitry 800 and bus bias circuitry 700 of FIG. 7.

Here, in bus bias circuitry 800, the gate of NMOS5 is controlled by a new n-channel metal oxide semiconductor field effect transistor (“NMSFET6” or “NMOS6” in short) which is controlled by resistor R72 and Zener diode D23. This configuration changes some the fault codes reported by the transceiver, but the transceiver is able to protect the IC pins.

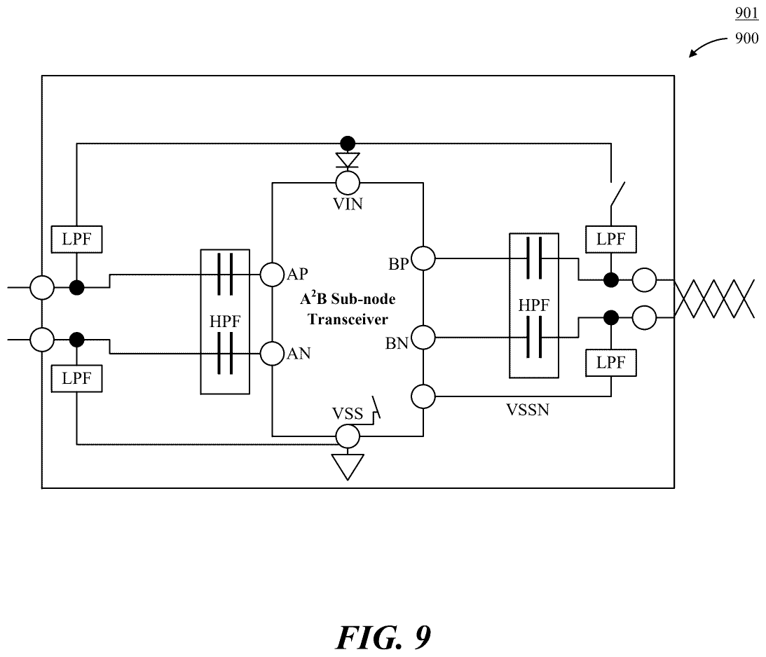

Referring to FIG. 9, conventional A2B bus circuitry 900 in a bus powered sub (BPS) node 901 is shown.

The A2B bus circuitry 900 includes various high pass filters (HPFs) and low pass filters (LPFs) for filtering power and/or data transmitting and received by the node transceiver 120.

The A2B bus circuitry 900 includes at least the following pins:
VIN—power supply input pin; and
VSS—Power Supply Pin for Return Currents.

In conventional A2B bus circuitry 900, a short to battery fault during operation will cause the entire battery voltage to appear across the VIN-VSS pins of the BPS node 901, which will damage the IC in case of a 48V battery short.

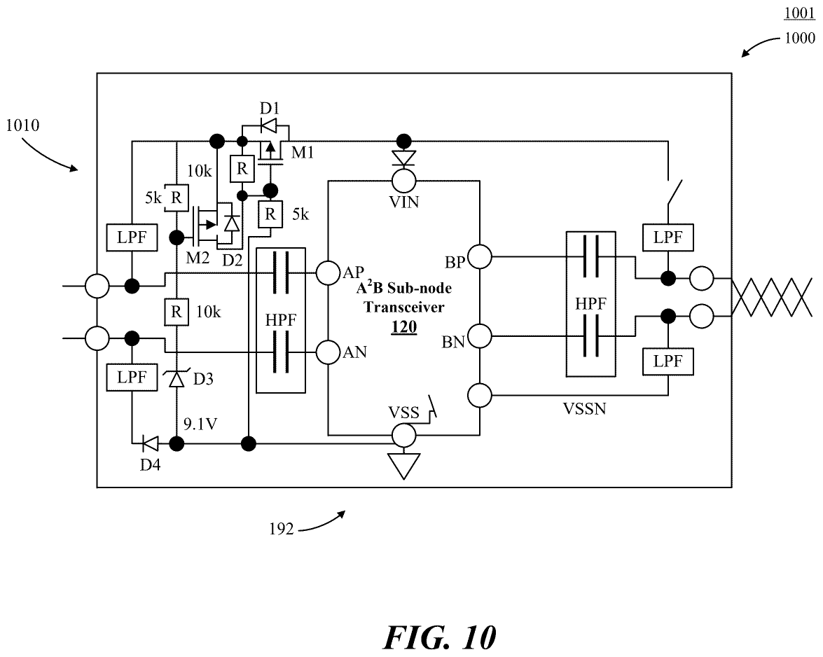

Referring to FIG. 10, example A2B bus circuitry 1000 in a bus powered sub (BPS) node 1001 is shown, in accordance with an exemplary aspect. A2B bus circuitry 1000 corresponds to an implementation of the over-voltage protection circuit 191 relating to a fifth solution of the present disclosure.

In A2B bus circuitry 1000, a MOSFET based switching circuit 1010 is used for over-voltage protection on the VIN pin. The MOSTFET based switching circuit 1010 includes 2 5 kΩ resistors and 2 10 kΩ resistors R, a MOSFET M1, a MOSFET M2, a Diode D3, and a Diode D4. MOSFET M1 includes an intrinsic (body) diode D1. MOSFET M2 includes an intrinsic (body) diode D2.

In A2B bus circuitry 1000, M1 is added to cutoff the power supply to the 120 transceiver when there is a high voltage. M2 along with D3 detect over-voltage events and disable M1 by connecting its gate to source. D4 is placed to protect the AN and Sub Node Ground from shorts to high voltage.

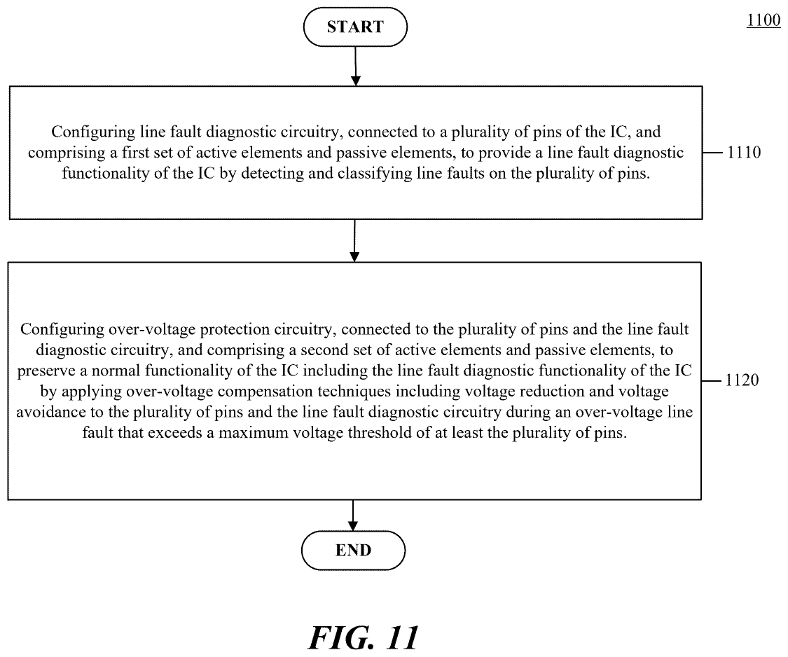

Referring to FIG. 11, an example method 1100 for protecting an integrated circuit (IC) having a plurality of pins from an over-voltage fault is shown, in accordance with an exemplary aspect.

At block 1110, the method 1100 includes configuring line fault diagnostic circuitry 190, connected to a plurality of pins 192 of the IC, and comprising a first set of active elements and passive elements, to provide a line fault diagnostic functionality of the IC by detecting and classifying line faults on the plurality of pins 192.

At block 1120, the method 1100 includes configuring over-voltage protection circuitry 191, connected to the plurality of pins 192 and the line fault diagnostic circuitry 190, and comprising a second set of active elements (e.g., NMOS5, DNMOS5, D25, D23, D20, D21, D7, D24) and passive elements (e.g., R72, C110, R71, R70), to preserve a normal functionality of the IC including the line fault diagnostic functionality of the IC by applying over-voltage compensation techniques including voltage reduction and voltage avoidance to the plurality of pins 192 and the line fault diagnostic circuitry 190 during an over-voltage line fault that exceeds a maximum voltage threshold of at least the plurality of pins 192. In an aspect, the maximum voltage threshold of at least the plurality of pins 192 is equal to an absolute maximum voltage rating (AMVR) of at least the plurality of pins 192. In an aspect, at least some of the plurality of pins 192 are included in the line fault diagnostic circuitry 191 such as VSENSEP, ISENSEP, VSENSEN, and ISENSEN. In an aspect, preserve a normal functionality of the IC means to preserve the functions of the IC despite exposure of the IC to the over-voltage fault such that the functions of the IC operate in the same manner after exposure to the over-voltage fault as before exposure to the over-voltage fault. Normal functionality of the IC includes diagnostic functions of the IC (e.g., line fault diagnostic functions) and non-diagnostic functions of the IC. In this case, the non-diagnostic functions of the IC include transceiver functions and so forth.

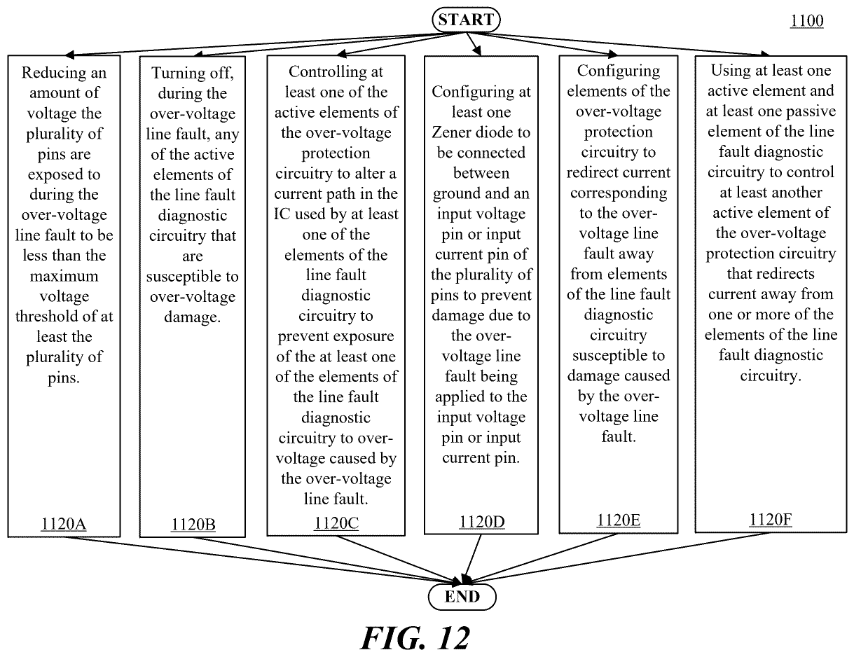

Referring to FIG. 12, further blocks of example method 1100 are shown, in accordance with an exemplary aspect.

In an aspect, block 1120 may include one or more of blocks 1120A through 1120F.

At block 1120A, in an aspect related to voltage reduction, the method 1100 includes reducing an amount of voltage the plurality of pins 192 are exposed to during the over-voltage line fault to be less than the maximum voltage threshold of at least the plurality of pins 192.

At block 1120B, in an aspect related to voltage avoidance, the method 1100 includes turning off, during the over-voltage line fault, any of the active elements of the line fault diagnostic circuitry 190 that are susceptible to over-voltage damage.

At block 1120C, in an aspect related to voltage avoidance the method 1100 includes controlling at least one of the active elements of the over-voltage protection circuitry 191 to alter a current path in the IC used by at least one of the elements of the line fault diagnostic circuitry 190 to prevent exposure of the at least one of the elements of the line fault diagnostic circuitry 190 to over-voltage caused by the over-voltage line fault.

At block 1120D, in an aspect related to voltage avoidance the method 1100 includes configuring at least one Zener diode (e.g., D21, D23) to be connected between ground and an input voltage pin or input current pin of the plurality of pins to prevent damage due to the over-voltage line fault being applied to the input voltage pin or input current pin.

At block 1120E, in an aspect related to voltage avoidance the method 1100 includes configuring elements of the over-voltage protection circuitry 191 to redirect current corresponding to the over-voltage line fault away from elements of the line fault diagnostic circuitry 190 susceptible to damage caused by the over-voltage line fault.

At block 1120F, in an aspect related to voltage avoidance the method 1100 includes using at least one active element (e.g., D23) and at least one passive element (e.g., R72) of the line fault diagnostic circuitry 190 to control at least another active element (e.g., NMOS5) of the over-voltage protection circuitry 191 that redirects current away from one or more of the elements (e.g., VSENSEN, ISENSEN) of the line fault diagnostic circuitry 190. It is to be appreciated that VSENSEN and ISENSEN are part of the plurality of pins 192 as well as part of the line fault diagnostic circuitry 190. The “VSENSEN” pin functions as a voltage sensing input, meaning it allows the line fault diagnostic circuitry to monitor the voltage level at a specific point in the circuit, to detect abnormal voltage conditions. Similarly, the “ISENSEN” pin functions as a current sensing input, meaning it allows the line fault diagnostic circuitry to monitor the current level at a specific point in the circuit, to detect abnormal current conditions. By shielding pins such as VSENSEN and ISENSEN from over-voltage, the elements of the line fault diagnostic circuitry 190 connected to these pins will also be shielded from the over-voltage.

It is to be appreciated that the use of transistor-based elements such as MOSFETS (NMOS5, NMOS6, etc.) can involve stopping the flow of current through a normally available path and/or creating a path that is normally blocked. In this way, flexibility is obtained in the use of such active elements to redirect current from circuit elements susceptible to damage caused by an over-voltage fault.

In the following detailed description, reference is made to the accompanying drawings which form a part hereof wherein like numerals designate like parts throughout, and in which is shown by way of illustration aspects that may be practiced. It is to be understood that other aspects may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described aspect. Various additional operations may be performed and/or described operations may be omitted in additional aspects.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

Various components may be referred to or illustrated herein in the singular (e.g., a “processor,” a “peripheral device,” etc.), but this is simply for ease of discussion, and any element referred to in the singular may include multiple such elements in accordance with the teachings herein.

The description uses the phrases “in an aspect” or “in aspects,” which may each refer to one or more of the same or different aspects. Furthermore, the terms “comprising,” “including,” “having,” and the like, as used with respect to aspects of the present disclosure, are synonymous. As used herein, the term “circuitry” may refer to, be part of, or include an application-specific integrated circuit (ASIC), an electronic circuit, and optical circuit, a processor (shared, dedicated, or group), and/or memory (shared, dedicated, or group) that execute one or more software or firmware programs, a combinational logic circuit, and/or other suitable hardware that provide the described functionality.

Aspects of the present disclosure may be implemented according to any one or any combination of the following clauses.

Clause 1. An integrated circuit (IC), comprising: a plurality of pins; line fault diagnostic circuitry, connected to the plurality of pins, and comprising a first set of active elements and passive elements, configured to provide a line fault diagnostic functionality of the IC by detecting and classifying line faults on the plurality of pins; and over-voltage protection circuitry, connected to the plurality of pins and the line fault diagnostic circuitry, and comprising a second set of active elements and passive elements, configured to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

Clause 2. The integrated circuit in accordance with clause 1, wherein the maximum voltage threshold of at least the plurality of pins is equal to an absolute maximum voltage rating (AMVR) of at least the plurality of pins.

Clause 3. The integrated circuit in accordance with any preceding clauses, wherein the over-voltage protection circuitry is configured to protect the plurality of pins and the line fault diagnostic circuitry of the IC from the over-voltage line fault by reducing an amount of voltage the plurality of pins are exposed to during the over-voltage line fault to be less than the maximum voltage threshold of at least the plurality of pins.

Clause 4. The integrated circuit in accordance with any preceding clauses, wherein the over-voltage protection circuitry is configured to protect the plurality of pins and the line fault diagnostic circuitry of the IC from the over-voltage line fault by turning off, during the over-voltage line fault, any of the active elements of the line fault diagnostic circuitry that are susceptible to over-voltage damage.

Clause 5. The integrated circuit in accordance with any preceding clauses, wherein the over-voltage protection circuitry is configured to protect the plurality of pins and the line fault diagnostic circuitry of the IC from the over-voltage line fault by controlling at least one of the active elements of the over-voltage protection circuitry to alter a current path in the IC used by at least one of the elements of the line fault diagnostic circuitry to prevent exposure of the at least one of the elements of the line fault diagnostic circuitry to over-voltage caused by the over-voltage line fault.

Clause 6. The integrated circuit in accordance with any preceding clauses, wherein the over-voltage protection circuitry comprises at least one Zener diode connected between ground and an input voltage pin or input current pin to prevent damage due to the over-voltage line fault.

Clause 7. The integrated circuit in accordance with any preceding clauses, wherein elements of the over-voltage protection circuitry are configured to redirect current corresponding to the over-voltage line fault away from elements of the line fault protection circuit susceptible to damage caused by the over-voltage line fault.

Clause 8. The integrated circuit in accordance with any preceding clauses, wherein the over-voltage protection circuitry uses at least one active element and at least one passive element of the over-voltage protection circuitry to control at least another active element of the over-voltage protection circuitry that redirects current away from one or more of the elements of the line fault diagnostic circuitry.

Clause 9. The integrated circuit in accordance with any preceding clauses, wherein the IC is an Automotive Audio Bus (A2B) IC configured for use as an A2B main node or an A2B local powered sub node.

Clause 10. The integrated circuit in accordance with any preceding clauses, wherein the IC is an Automotive Audio Bus (A2B) IC configured for use as an A2B bus powered sub node.

Clause 11. A method for protecting an integrated circuit (IC), comprising: configuring line fault diagnostic circuitry, connected to a plurality of pins of the IC, and comprising a first set of active elements and passive elements, to provide a line fault diagnostic functionality of the IC by detecting and classifying line faults on the plurality of pins; and configuring over-voltage protection circuitry, connected to the plurality of pins and the line fault diagnostic circuitry, and comprising a second set of active elements and passive elements, to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

Clause 12. The method in accordance with clause 11, wherein the maximum voltage threshold of at least the plurality of pins is equal to an absolute maximum voltage rating (AMVR) of at least the plurality of pins.

Clause 13. The method in accordance with any preceding clauses, wherein configuring the over-voltage protection circuitry to protect the plurality of pins and the line fault diagnostic circuitry of the IC from the over-voltage line fault comprises reducing an amount of voltage the plurality of pins are exposed to during the over-voltage line fault to be less than the maximum voltage threshold of at least the plurality of pins.

Clause 14. The method in accordance with any preceding clauses, wherein configuring the over-voltage protection circuitry to protect the plurality of pins and the line fault diagnostic circuitry of the IC from the over-voltage line fault comprises turning off, during the over-voltage line fault, any of the active elements of the line fault diagnostic circuitry that are susceptible to over-voltage damage.

Clause 15. The method in accordance with any preceding clauses, wherein configuring the over-voltage protection circuitry to protect the plurality of pins and the line fault diagnostic circuitry of the IC from the over-voltage line fault comprises controlling at least one of the active elements of the over-voltage protection circuitry to alter a current path in the IC used by at least one of the elements of the line fault diagnostic circuitry to prevent exposure of the at least one of the elements of the line fault diagnostic circuitry to over-voltage caused by the over-voltage line fault.

Clause 16. The method in accordance with any preceding clauses, wherein configuring the over-voltage protection circuitry to protect the plurality of pins and the line fault diagnostic circuitry of the IC from the over-voltage line fault comprises configuring at least one Zener diode to be connected between ground and an input voltage pin or input current pin of the plurality of pins to prevent a short to ground condition due to the over-voltage line fault being applied to the input voltage pin or input current pin.

Clause 17. The method in accordance with any preceding clauses, wherein configuring the over-voltage protection circuitry to protect the plurality of pins and the line fault diagnostic circuitry of the IC from the over-voltage line fault comprises configuring elements of the over-voltage protection circuitry to redirect current corresponding to the over-voltage line fault away from elements of the line fault diagnostic circuitry susceptible to damage caused by the over-voltage line fault.

Clause 18. The method in accordance with any preceding clauses, wherein configuring the over-voltage protection circuitry to protect the plurality of pins and the line fault diagnostic circuitry of the IC from the over-voltage line fault comprises using at least one active element and at least one passive element of the line fault diagnostic circuitry to control at least another active element of the over-voltage protection circuitry that redirects current away from one or more of the elements of the line fault diagnostic circuitry.

Clause 19. The method in accordance with any preceding clauses, wherein the IC is an Automotive Audio Bus (A2B) IC configured for use as an A2B main node or an A2B local powered sub node.

Clause 20. The method in accordance with any preceding clauses, wherein the IC is an Automotive Audio Bus (A2B) IC configured for use as an A2B bus powered sub node.

### Variations and Implementations

Having thus described several aspects and aspects of the technology of this application, it is to be appreciated that various alterations, modifications, and improvements will readily occur to those of ordinary skill in the art. Such alterations, modifications, and improvements are intended to be within the spirit and scope of the technology described in the application. For example, those of ordinary skill in the art will readily envision a variety of other means and/or structures for performing the function and/or obtaining the results and/or one or more of the advantages described herein, and each of such variations and/or modifications is deemed to be within the scope of the aspects described herein.

Those skilled in the art will recognize or be able to ascertain using no more than routine experimentation, many equivalents to the specific aspects described herein. It is, therefore, to be understood that the foregoing aspects are presented by way of example only and that, within the scope of the appended claims and equivalents thereto, inventive aspects may be practiced otherwise than as specifically described. In addition, any combination of two or more features, systems, articles, materials, kits, and/or methods described herein, if such features, systems, articles, materials, kits, and/or methods are not mutually inconsistent, is included within the scope of the present disclosure.

The foregoing outlines features of one or more aspects of the subject matter disclosed herein. These aspects are provided to enable a person having ordinary skill in the art (PHOSITA) to better understand various aspects of the present disclosure. Certain well-understood terms, as well as underlying technologies and/or standards may be referenced without being described in detail. It is anticipated that the PHOSITA will possess or have access to background knowledge or information in those technologies and standards sufficient to practice the teachings of the present disclosure.

The PHOSITA will appreciate that they may readily use the present disclosure as a basis for designing or modifying other processes, structures, or variations for carrying out the same purposes and/or achieving the same advantages of the aspects introduced herein. The PHOSITA will also recognize that such equivalent constructions do not depart from the spirit and scope of the present disclosure, and that they may make various changes, substitutions, and alterations herein without departing from the spirit and scope of the present disclosure.

In some aspects, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processors (inclusive of digital signal processors, microprocessors, supporting chipsets, etc.), memory elements, etc. can be suitably coupled to the board based on particular configuration needs, processing demands, computer designs, etc.

Other components such as external storage, additional sensors, controllers for audio/video display, and peripheral devices may be attached to the board as plug-in cards, via cables, or integrated into the board itself. In another example aspect, the electrical circuits of the FIGURES may be implemented as standalone modules (e.g., a device with associated components and circuitry configured to perform a specific application or function) or implemented as plug-in modules into application-specific hardware of electronic devices.

Note that with the numerous examples provided herein, interaction may be described in terms of two, three, four, or more electrical components. However, this has been done for purposes of clarity and example only. It should be appreciated that the system can be consolidated in any suitable manner. Along similar design alternatives, any of the illustrated components, modules, and elements of the FIGURES may be combined in various possible configurations, all of which are clearly within the broad scope of this disclosure.

In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations. Accordingly, the examples provided should not limit the scope or inhibit the broad teachings of the electrical circuits as potentially applied to a myriad of other architectures.

Also, as described, some aspects may be embodied as one or more methods. The acts performed as part of the method may be ordered in any suitable way. Accordingly, aspects may be constructed in which acts are performed in an order different than illustrated, which may include performing some acts simultaneously, even though shown as sequential acts in illustrative aspects.

### Interpretation of Terms

All definitions, as defined and used herein, should be understood to control over dictionary definitions, definitions in documents incorporated by reference, and/or ordinary meanings of the defined terms. Unless the context clearly requires otherwise, throughout the description and the claims:
“comprise,” “comprising,” and the like are to be construed in an inclusive sense, as opposed to an exclusive or exhaustive sense; that is to say, in the sense of “including, but not limited to”.
“connected,” “coupled,” or any variant thereof, means any connection or coupling, either direct or indirect, between two or more elements; the coupling or connection between the elements can be physical, logical, or a combination thereof.
“herein,” “above,” “below,” and words of similar import, when used to describe this specification shall refer to this specification as a whole and not to any particular portions of this specification.
“or,” in reference to a list of two or more items, covers all of the following interpretations of the word: any of the items in the list, all of the items in the list, and any combination of the items in the list.
the singular forms “a”, “an” and “the” also include the meaning of any appropriate plural forms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined.

Elements other than those specifically identified by the “and/or” clause may optionally be present, whether related or unrelated to those elements specifically identified. Thus, as a non-limiting example, a reference to “A and/or B”, when used in conjunction with open-ended language such as “comprising” may refer, in one aspect, to A only (optionally including elements other than B); in another aspect, to B only (optionally including elements other than A); in yet another aspect, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

Thus, as a non-limiting example, “at least one of A and B” (or, equivalently, “at least one of A or B,” or, equivalently “at least one of A and/or B”) may refer, in one aspect, to at least one, optionally including more than one, A, with no B present (and optionally including elements other than B); in another aspect, to at least one, optionally including more than one, B, with no A present (and optionally including elements other than A); in yet another aspect, to at least one, optionally including more than one, A, and at least one, optionally including more than one, B (and optionally including other elements); etc.

As used herein, the term “between” is to be inclusive unless indicated otherwise. For example, “between A and B” includes A and B unless indicated otherwise.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke 35 U.S.C. § 112(f) as it exists on the date of the filing hereof unless the words “means for” or “steps for” are specifically used in the particular claims; and (b) does not intend, by any statement in the disclosure, to limit this disclosure in any way that is not otherwise reflected in the appended claims.

The present invention should therefore not be considered limited to the particular aspects described above. Various modifications, equivalent processes, as well as numerous structures to which the present invention may be applicable, will be readily apparent to those skilled in the art to which the present invention is directed upon review of the present disclosure.

It should be understood that the detailed description and specific examples, while indicating exemplary aspects of the systems and methods are intended for purposes of illustration only and are not intended to limit the scope. These and other features, aspects, and advantages of the systems and methods of the present invention can be better understood from the description, appended claims or aspects, and accompanying drawings. It should be understood that the Figures are merely illustrative and are not drawn to scale. It should also be understood that the same reference numerals are used throughout the figures to indicate the same or similar parts.

Other variations to the disclosed aspects can be understood and effected by those skilled in the art in practicing the disclosure, from a study of the drawings, the disclosure, and the appended aspects or claims. In the aspects or claims, the word “comprising” does not exclude other elements or steps, and the indefinite article “a” or “an” does not exclude a plurality. The mere fact that certain measures are recited in mutually different dependent aspects or claims does not indicate that a combination of these measures cannot be used to advantage. Any reference signs in the claims should not be construed as limited the scope.

What is claimed is:

1. An integrated circuit (IC), comprising:
a plurality of pins;
line fault diagnostic circuitry, connected to the plurality of pins, and comprising a first set of active elements and passive elements, configured to provide a line fault diagnostic functionality of the IC by detecting and classifying line faults on the plurality of pins; and
over-voltage protection circuitry, connected to the plurality of pins and the line fault diagnostic circuitry, and comprising a second set of active elements and passive elements, configured to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

2. The integrated circuit in accordance with claim 1, wherein the maximum voltage threshold of at least the plurality of pins is equal to an absolute maximum voltage rating (AMVR) of at least the plurality of pins.

3. The integrated circuit in accordance with claim 1, wherein the over-voltage protection circuitry is configured to preserve the normal functionality of the IC including the line fault diagnostic functionality of the IC by reducing an amount of voltage the plurality of pins are exposed to during the over-voltage line fault to be less than the maximum voltage threshold of at least the plurality of pins.

4. The integrated circuit in accordance with claim 1, wherein the over-voltage protection circuitry is configured to preserve the normal functionality of the IC including the line fault diagnostic functionality of the IC by turning off, during the over-voltage line fault, active elements of the line fault diagnostic circuitry that are susceptible to over-voltage damage.

5. The integrated circuit in accordance with claim 1, wherein the over-voltage protection circuitry is configured to preserve the normal functionality of the IC including the line fault diagnostic functionality of the IC by controlling at least one active element of the over-voltage protection circuitry to alter a current path in the IC used by at least one element of the line fault diagnostic circuitry to prevent exposure of the at least one element of the line fault diagnostic circuitry to over-voltage caused by the over-voltage line fault.

6. The integrated circuit in accordance with claim 1, wherein the over-voltage protection circuitry comprises at least one Zener diode connected between ground and an input voltage pin or input current pin to prevent damage due to the over-voltage line fault.

7. The integrated circuit in accordance with claim 1, wherein elements of the over-voltage protection circuitry are configured to redirect current corresponding to the over-voltage line fault away from elements of the line fault diagnostic circuitry susceptible to damage caused by the over-voltage line fault.

8. The integrated circuit in accordance with claim 1, wherein the over-voltage protection circuitry uses at least one active element and at least one passive element of the over-voltage protection circuitry to control at least another active element of the over-voltage protection circuitry that redirects current away from one or more line fault diagnostic circuitry elements of the line fault diagnostic circuitry.

9. The integrated circuit in accordance with claim 1, wherein the IC is an Automotive Audio Bus (A2B) IC configured for use as an A2B main node or an A2B local powered sub node.

10. The integrated circuit in accordance with claim 1, wherein the IC is an Automotive Audio Bus (A2B) IC configured for use as an A2B bus powered sub node.

11. A method for protecting an integrated circuit (IC), comprising:
configuring line fault diagnostic circuitry, connected to a plurality of pins of the IC, and comprising a first set of active elements and passive elements, to provide a line fault diagnostic functionality of the IC by detecting and classifying line faults on the plurality of pins; and
configuring over-voltage protection circuitry, connected to the plurality of pins and the line fault diagnostic circuitry, and comprising a second set of active elements and passive elements, to preserve a normal functionality of the IC including the line fault diagnostic functionality of the IC by applying over-voltage compensation techniques including voltage reduction and voltage avoidance to the plurality of pins and the line fault diagnostic circuitry during an over-voltage line fault that exceeds a maximum voltage threshold of at least the plurality of pins.

12. The method in accordance with claim 11, wherein the maximum voltage threshold of at least the plurality of pins is equal to an absolute maximum voltage rating (AMVR) of at least the plurality of pins.

13. The method in accordance with claim 11, wherein configuring the over-voltage protection circuitry to preserve the normal functionality of the IC including the line fault diagnostic functionality of the IC comprises reducing an amount of voltage the plurality of pins are exposed to during the over-voltage line fault to be less than the maximum voltage threshold of at least the plurality of pins.

14. The method in accordance with claim 11, wherein configuring the over-voltage protection circuitry to preserve the normal functionality of the IC including the line fault diagnostic functionality of the IC comprises turning off, during the over-voltage line fault, active elements of the line fault diagnostic circuitry that are susceptible to over-voltage damage.

15. The method in accordance with claim 11, wherein configuring the over-voltage protection circuitry to preserve the normal functionality of the IC including the line fault diagnostic functionality of the IC comprises controlling at least one active element of the over-voltage protection circuitry to alter a current path in the IC used by at least one element of the line fault diagnostic circuitry to prevent exposure of the at least one element of the line fault diagnostic circuitry to over-voltage caused by the over-voltage line fault.

16. The method in accordance with claim 11, wherein configuring the over-voltage protection circuitry to preserve the normal functionality of the IC including the line fault diagnostic functionality of the IC comprises configuring at least one Zener diode to be connected between ground and an input voltage pin or input current pin of the plurality of pins to prevent a short to ground condition due to the over-voltage line fault being applied to the input voltage pin or input current pin.

17. The method in accordance with claim 11, wherein configuring the over-voltage protection circuitry to preserve the normal functionality of the IC including the line fault diagnostic functionality of the IC comprises configuring elements of the over-voltage protection circuitry to redirect current corresponding to the over-voltage line fault away from elements of the line fault diagnostic circuitry susceptible to damage caused by the over-voltage line fault.

18. The method in accordance with claim 11, wherein configuring the over-voltage protection circuitry to preserve the normal functionality of the IC including the line fault diagnostic functionality of the IC comprises using at least one active element and at least one passive element of the line fault diagnostic circuitry to control at least another active element of the over-voltage protection circuitry that redirects current away from one or more elements of the line fault diagnostic circuitry.

19. The method in accordance with claim 11, wherein the IC is an Automotive Audio Bus (A2B) IC configured for use as an A2B main node or an A2B local powered sub node.

20. The method in accordance with claim 11, wherein the IC is an Automotive Audio Bus (A2B) IC configured for use as an A2B bus powered sub node.
